(19) United States
(12) Patent Application Publication
(10) Pub. No.: US 2006/0071151 A1
(43) Pub. Date: Apr. 6, 2006

(54) Semiconductor optical sensor device and range finding method using the same

(75) Inventors: Hajime Fukamura, Nagano (JP); Akio Izumi, Nagano (JP)

Correspondence Address: KANESAKA BERNER AND PARTNERS LLP, SUITE 300, 1700 DIAGONAL RD, ALEXANDRIA, VA, 22314-2848, US

(73) Assignee: FUJI ELECTRIC DEVICE TECHNOLOGY CO., LTD., Tokyo (JP)

(21) Appl. No.: 11/196,306

(22) Filed: Aug. 4, 2005

(30) Foreign Application Priority Data
Oct. 6, 2004 (JP) 2004-293778

(51) Int. Cl. H01L 31/00

(52) U.S. Cl. 250/214.1

(57) ABSTRACT

A semiconductor optical sensor device includes a lens, a semiconductor optical sensor chip, onto which an object image is formed via the lens, and a transparent filler which is filled into a space between lens and optical sensor chip and which exhibits a high thermal conductivity. The optical sensor chip includes a semiconductor temperature sensor capable of measuring the temperature of lens via the transparent filler 9.

### BACKGROUND OF THE INVENTION AND RELATED ART STATEMENT

The present invention relates to a semiconductor optical sensor device mounting a semiconductor optical sensor chip and one or more lenses for forming an object image on the semiconductor optical sensor chip. The present invention relates also to a range finding method using the semiconductor optical sensor device.

FIG. 17 is a perspective view showing a conventional semiconductor optical sensor device (hereinafter referred to as an “optical sensor device”) of a single lens type, which incorporates therein a charge coupled device (CCD) image sensor chip or a metal oxide semiconductor (MOS) image sensor chip as a semiconductor optical sensor chip (hereinafter referred to as an “optical sensor chip”). The conventional optical sensor device includes a plastic casing 31 housing a not shown semiconductor optical sensor chip therein, a diaphragm plate 32 fixed to plastic casing 31, and a lens holder 33 arranged on the upper surface of diaphragm plate 32. A lens 33a for forming the image of an object on the optical sensor chip is mounted in lens holder 33.

The optical sensor device is, as shown in FIG. 17, mounted on a circuit board 34 which can take the form a printed circuit board which can be either conventional or flexible circuit board and which is provided with a wiring lead frame 35.

In this arrangement, the lens 33a deforms slightly in response to a change in temperature of either the optical sensor chip itself or a change in ambient temperature (viz., a change in the environmental temperature). This causes a change in the focal length of the optical sensor device. Therefore, the light amount that the optical sensor chip intercepts and the position, at which the image of an object is formed, are changed. To obviate this problem, a temperature sensor 36 such as a thermistor or a silicon temperature sensor is mounted on lens holder 33 to detect the temperature of lens holder 33 and to correct the focal length in accordance with the detected temperature.

FIG. 18 is a perspective view of another conventional semiconductor optical sensor device as a range finder. This arrangement includes a pair of lens 43P comprising lenses 43a and 43b. This conventional optical sensor device includes a plastic casing 41 housing a not shown semiconductor optical sensor chip therein, a diaphragm plate 42 fixed to plastic casing 41. The pair lens 43P are arranged on the end face of diaphragm plate 42. A circuit board 44 and a lead frame 45 are arranged in the manner shown in FIG. 18.

In this conventional optical sensor device, the focal lengths of lenses 43a and 43b in lens pair 43P, the baseline length between lenses 43a and 43b, and the distance between lens pair 43P and the optical sensor chip are changed slightly by the temperature change of the optical sensor chip or by a change in ambient temperature. As a result, the amount of light that the optical sensor chip intercepts and the positions, at which the images of an object are formed, are changed, adversely affecting the results of range finding.

To obviate this problem, a temperature sensor 46 is mounted on the side face of lens pair 43P to detect the temperature of lens pair 43P. The output of this temperature sensor 46 is used to correct one or both of the focal length or the baseline length.

The temperature correcting arrangement of the nature described above is employed, by way of example, in the range finder described in Japanese patent document Hei.11(1999)-166825A. The range finder described in this Patent Document utilizes a thermistor and temperature detecting means which are secured to the range finding unit, which in this instance, includes lenses and image sensor arrays.

The automatic focusing sensor described in Japanese patent document Hei.9(1997)-311082A, on the other hand, employs another conventional technique which facilitates temperature correction. This conventional automatic focusing sensor includes a CCD linear sensor that uses a temperature detector in the form of a MOS transistor which is mounted on the same chip as the CCD linear sensor.

The conventional techniques described in connection with FIGS. 17 and 18 and in the patent document Hei.11(1999)-166825A detect the temperature in the vicinity of the lens or the temperature of the lens and correct the optical characteristics of the lens based on the detected temperature. However, the costs of the parts and elements constituting the temperature sensor and the process of mounting the temperature sensor markedly increase the manufacturing costs of the conventional optical sensor devices and complicate the process of assembling the same.

Since it is necessary to provide space for mounting a temperature sensor in the vicinity of the lens, the space for the temperature sensor represents an impediment to down sizing cameras and such type of optical instruments/devices. Further, when a temperature sensor is mounted adjacent to a constituent part that works as a heat source, the temperature detected by the temperature sensor is not always equal to the lens temperature. In other words, the temperature detected by the temperature sensor may contain some error.

The conventional technique described in the patent document Hei.9(1997)-311082A is capable of detecting the temperature of the CCD linear sensor but not the lens temperature.

In order to perform temperature corrections accurately, it is necessary to accurately detect the lens temperature, since the thermal expansion coefficient of the lens and such optical parts is larger than the thermal expansion coefficient of the chip or of a CCD linear sensor. However, it is impossible for the conventional technique described in the patent document Hei.9(1997)-311082A accurately detecting the lens temperature and to conduct temperature corrections. Moreover, when a heat source is located in the vicinity of the optical sensor chip, the temperature detected by the temperature sensor is affected adversely by the heat source.

In view of the foregoing, it is a first object of the invention to obviate the problems described above.

It is a second object of the invention to provide a semiconductor optical sensor device that incorporates a temperature sensor in a semiconductor optical sensor chip and facilitates measuring the lens temperature essentially without error.

It is a third object of the invention to provide a semiconductor optical sensor device unnecessary to secure any space for mounting a temperature sensor.

It is a fourth object of the invention to provide a range finding method that facilitates correcting the positions of light interception on the optical sensor chip and the baseline length between the lenses based on the lens temperature measured by the temperature sensor and to measure the object distance accurately.

### SUMMARY OF THE INVENTION

According to a first aspect of the invention, a semiconductor optical sensor device features a focusing means focusing the light from an object; a semiconductor optical sensor chip, on which the image of the object is formed through the focusing means; a transparent filler between the focusing means and the semiconductor optical sensor chip, the transparent filler exhibiting a high thermal conductivity; and the semiconductor optical sensor chip including a temperature sensor that measures the temperature of the focusing means via the transparent filler.

According to this aspect of the invention, the semiconductor optical sensor device is such that the focusing means is a lens that forms the image of the object on the semiconductor optical sensor chip to pick up the image of the object. In a given embodiment, the focusing means can comprise a lens that focuses the reflected light from the object reflecting the light irradiated from an external light emitting means; and the semiconductor optical sensor device can further include a calculating means that calculates the distance between the lens and the object based on the principle of triangulation using the temperature measured by the temperature sensor, the distance between the light emitting means and the lens, the position of light interception on the semiconductor optical sensor chip, at which the reflected light via the lens is intercepted, and the distance between the lens and the semiconductor optical sensor chip.

Further, the semiconductor optical sensor device can be such that the focusing means is a pair of lenses; and the semiconductor optical sensor device further includes a calculating means that calculates the distance between the pair of lenses and the object based on the principle of triangulation using the temperature measured by the temperature sensor, the baseline length between the lenses, the positions of light interception on the semiconductor optical sensor chip, at which the light via the lenses is intercepted, and the distance between the lenses and the semiconductor optical sensor chip.

In any of the above arrangements, the semiconductor optical sensor device can be such that the temperature sensor is a semiconductor temperature sensor that obtains the output voltage proportional to the temperature of the PN-junction of a semiconductor device formed in the semiconductor optical sensor chip.

A further aspect of the invention resides in a method of range finding. This method can use a semiconductor optical sensor device of the nature disclosed above and includes the steps of: correcting the position of light interception on the semiconductor optical sensor chip using the temperature difference between the temperature measured by the temperature sensor and a reference temperature; and measuring the distance between the lens and the object based on the principle of triangulation using the corrected position of light interception.

This method is such that using the semiconductor optical sensor device includes the steps of: obtaining the distance between the lens and the object based on the principle of triangulation without considering the temperature measured by the temperature sensor; and correcting the obtained distance using the temperature difference between the temperature measured by the temperature sensor and a reference temperature.

In another embodiment, the range finding method using the semiconductor optical sensor device, includes the steps of: correcting the baseline length between the lenses using the temperature difference between the temperature measured by the temperature sensor and a reference temperature; and measuring the distance between the lenses and the object based on the principle of triangulation using the corrected baseline length.

As will be appreciated, the invention is such that the lens temperature is accurately measured via a transparent filler included in a temperature sensor incorporated in the semiconductor optical sensor chip. By correcting the optical characteristics of the semiconductor optical sensor device based on the temperature measured by the temperature sensor, the range finding accuracy is improved. Especially in the case wherein a semiconductor temperature sensor is used as a temperature sensor. The error factors are reduced and the lens temperature can be measured very accurately. Further, since it is not necessary to mount the temperature sensor on the exterior of the device, the number of the constituent parts and elements is reduced, the processes of manufacture and assembly are simplified, and the times for manufacture and assembly are shortened.

In a nutshell, the semiconductor optical sensor device according to the invention improves the stability of the lens against temperature change by a relatively inexpensive structure and improves the accuracy of range finding by correcting the optical characteristics variations caused by temperature change.

The soft transparent filler protecting the semiconductor optical sensor chip also reduces the stress exerted to the chip greatly as compared with the conventional resin mold packaging.

### BRIEF DESCRIPTION OF THE DRAWINGS

FIG. 1 is a top plan view of a semiconductor optical sensor device according to a first embodiment of the invention.

FIG. 2 is a cross sectional view along section line 2-2 of FIG. 1.

FIG. 3 is a perspective view showing the external appearance of the semiconductor optical sensor device shown in FIG. 1.

FIG. 4 is a top plan view of a semiconductor optical sensor device according to a second embodiment of the invention.

FIG. 5 is a cross sectional view along section line 5-5 of FIG. 4.

FIG. 6 is a diagram describing the principle of range finding using the semiconductor optical sensor device according to the second embodiment.

FIG. 7 is a block circuit diagram of a circuit used in an embodiment of a semiconductor temperature sensor according to the invention.

FIG. 8 is a graph describing the typical characteristics of a temperature sensor.

FIG. 9 is a graph describing the shift in sensed distance which is corrected for in range finding semiconductor optical device such as used in the second embodiment.

FIG. 10 is schematic diagram depicting the system of an active automatic focusing system according to a third embodiment of the invention.

FIG. 11 is an enlarged schematic view of the semiconductor optical sensor device shown in FIG. 10.

FIG. 12 is a flow chart describing the steps involved in temperature correction for the automatic focusing system according to the third embodiment of the invention.

FIG. 13 is a flow chart describing the other steps of temperature correction for the automatic focusing system according to the third embodiment of the invention.

FIG. 14 is a block diagram of a range finder according to a fourth embodiment of the invention using the semiconductor optical sensor device according to the second embodiment.

FIG. 15 is a flow chart describing the initial adjustment steps carried out with the range finder shown in FIG. 14.

FIG. 16 is a flow chart describing the range finding steps carried out using the range finder shown in FIG. 14.

FIG. 17 is a perspective view showing a conventional single-lens-type semiconductor optical sensor device discussed in the opening paragraphs of the instant disclosure.

FIG. 18 is a perspective view of another conventional semiconductor optical sensor device including a pair of lenses also discussed above.

### DETAILED DESCRIPTION OF THE PREFERRED EMBODIMENTS

The invention will now be described in detail hereinafter with reference to the accompanied drawing figures which illustrate the preferred embodiments of the invention.

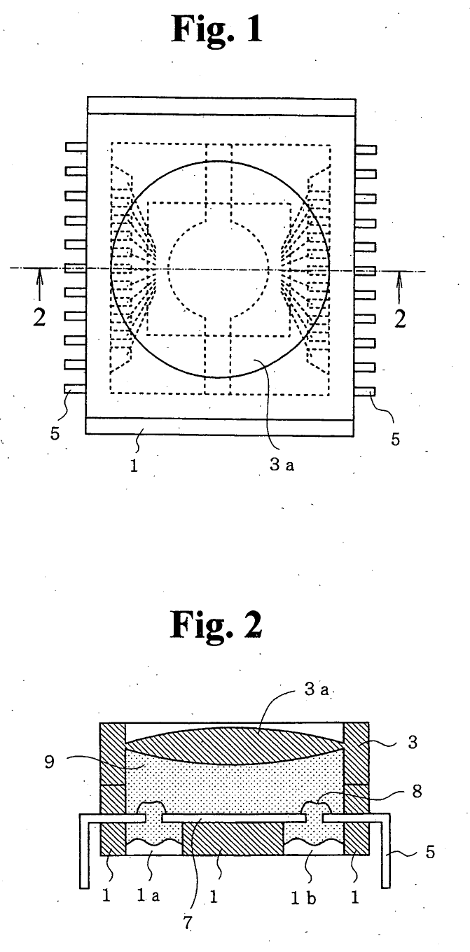

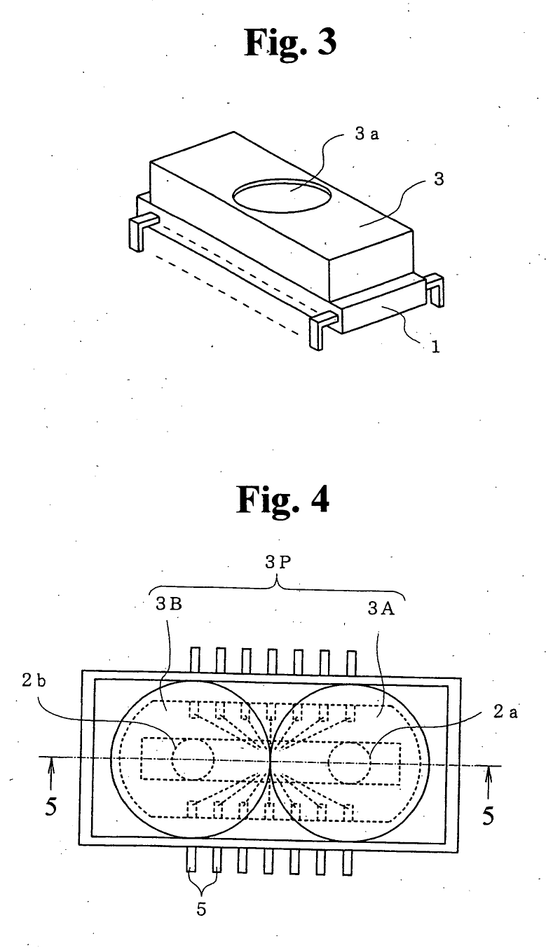

FIG. 1 is a top plan view of a semiconductor optical sensor device according to the first embodiment of the invention. FIG. 2 is a cross sectional view along the line segment 2-2 of FIG. 1. FIG. 3 is a perspective view showing the external appearance of the optical sensor device of FIG. 1.

The optical sensor device according to the first embodiment is a single-lens-type optical sensor device that functions to detect the existence of an object and pick up the object image.

Referring now to FIGS. 1 through 3, a semiconductor optical sensor chip 7 is bonded to the bottom of a plastic casing 1. Optical sensor chip 7 can, merely by way of example, be a CCD image sensor, a MOS image sensor, a photodiode, an infrared sensor, or such an optical sensor. Plastic casing 1 includes a bonding portion (the bottom), to which optical sensor chip 7 is bonded, a supporting portion that supports the bonding portion, and openings 1a and 1b formed in the portions of optical sensor chip 7 other than the bonding and supporting portions.

A semiconductor temperature sensor (hereinafter usually referred to as a “temperature sensor”) is incorporated in the surface of semiconductor optical sensor chip 7 by the semiconductor manufacturing process. The structure and the function of the temperature sensor will be described later.

Essentially L-shaped wiring lead frames 5 extend from within the plastic casing 1. The lead frames 5 are connected to the internal terminals on the surface of optical sensor chip 7 via bonding wires 8. A lens holder 3 is fixed to the upper circumference area of plastic casing 1. A lens 3a is integrated with lens holder 3 to form a unit.

It is preferable to use the same plastic material for casing 1 and lens holder 3 or to use materials which have a thermal expansion coefficients which are almost the same for both the plastic casing 1 and the lens holder 3. By selecting the same material for plastic casing 1 and lens holder 3 as described above, plastic casing 1 and lens holder 3 are expand and contract essentially uniformly in response to changes in ambient temperature, whereby the positional relations thereof unchanged and the focal point of lens 3a may be positioned on optical sensor chip 7.

Moreover, by simultaneously employing a temperature sensor in optical sensor chip 7 and a transparent filler as will described below, an optical sensor device exhibiting more stable optical characteristics is realized.

The space surrounded by the plastic casing 1, the lens holder 3, and lens 3a is filled with a transparent filler in the form of a silicone gel 9. This silicone gel 9 is exposed to ambient conditions via openings 1a and 1b. This silicone gel 9 exhibits a thermal conductivity of, for example, 0.17 [W/m·K] is used. Since the thermal conductivity of silicone gel 9, that is 0.17 [W/m·K], is higher than the thermal conductivity of air, that is 2.41×10⁻²[W/m·K] at 0° C. and 3.17×10⁻² [W/m·K] at 100° C. by about one-digit number, silicone gel 9 facilitates the accurate transmission of the temperature of lens 3a to the optical sensor chip 7.

As described above, optical sensor chip 7 and bonding wires 8 are sealed completely within and protected by silicone gel 9. Since the silicone gel 9 is exposed to ambient conditions via openings 1a and 1b, the volume change of silicone gel 9 including the expansion and the contraction caused by temperature changes is permitted by the openings 1a and 1b.

For example, a semiconductor temperature sensor combining a semiconductor PN-junction and a current mirror circuit may be used for the temperature sensor which is incorporated in optical sensor chip 7.

Since the silicone gel 9 exhibiting a high thermal conductivity is filled into the space between the temperature sensor and lens 3a, the temperature of the lens 3a is transmitted without causing any loss to the temperature sensor. Therefore, the temperature of lens 3a is measured almost without any error by the temperature sensor.

The temperature of lens 3a detected according to the first embodiment can be used for correcting the optical characteristics of so called active automatic focusing systems (AF systems) described later in connection with a third embodiment of the invention.

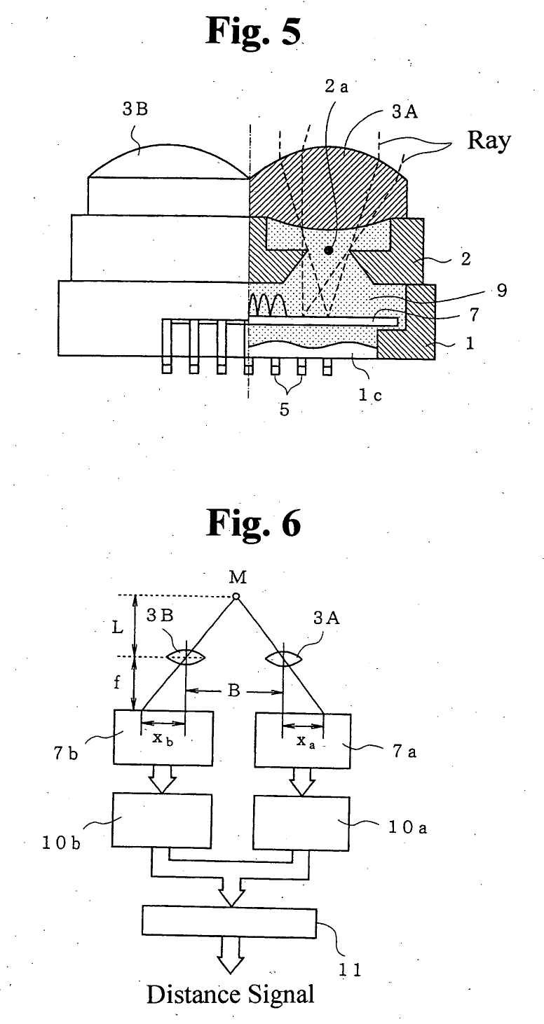

FIG. 4 is a top plan view of a semiconductor optical sensor device according to a second embodiment of the invention. FIG. 5 is a cross sectional view along section line 5-5 of FIG. 4. The optical sensor device according to this second embodiment is a range finder that includes an optical sensor chip including a pair lens formed of a pair of lenses and measures the object distance.

The principle of range finding by this kind of optical sensor devices will be described below with reference to FIG. 6.

Referring now to FIG. 6, images of an object M are formed through a pair of lenses 3A and 3B onto optical sensor arrays 7a and 7b such as CCD image sensors, MOS image sensors or the like. Quantizing circuits 10a and 10b convert the output signals from optical sensor arrays 7a and 7b to digital signals. A calculating circuit 11 calculates the distance L between lenses 3A, 3B and object M based on the output signals from quantizing circuits 10a and 10b. This distance L is given by the following equation (1) based on the principle of triangulation.
L=B·f/(xₐ+x_{b})=B·f/x (1)

In this equation:

B is the baseline length between lenses 3A and 3B (the distance between the center axes (optical axes));

f the distance between lenses 3A, 3B and optical sensor arrays 7a, 7b;

xₐ and x_{b} the distances on optical sensor arrays 7a and 7b between the actual positions of light interception and the positions of light interception for object M at the infinity point; and

x (=xₐ+x_{b}) the relative displacement (phase amount) of object M on optical sensor arrays 7a and 7b.

Calculating circuit 11 is capable of calculating the distance L by implementing equation (1) described above. The configuration shown in FIG. 6 schematically depicts a range finder for automatic focusing cameras. The principle of range finding described above is described in the publication of JP 2002-202121A. The structures according to the second embodiment shown in FIGS. 4 and 5 constitute the range finder as described above.

In FIG. 4, a lens pair 3P formed of lenses 3A, 3B and diaphragm holes 2a, 2b are shown. In FIG. 5, an opening 1c formed through plastic casing 1 and a diaphragm plate 2 are shown.

Optical sensor arrays 7a and 7b are formed on semiconductor optical sensor chip 7. A semiconductor temperature sensor is built in the surface of optical sensor chip 7 in the same manner as according to the first embodiment.

According to the second embodiment, the space surrounded by lenses 3A, 3B, diaphragm plate 2 and plastic casing 1 is filled with silicone gel 9 which exhibits a high thermal conductivity working as a transparent filler. The temperature of lenses 3A and 3B is transmitted without loss to the temperature sensor. Therefore, the temperature sensor facilitates measuring the temperature of lenses 3A and 3B essentially without error.

The object distance is measured accurately by correcting the baseline length B between lenses 3A and 3B and the distance between lenses 3A, 3B as described herein later based on the detected temperature.

The circuit configuration of the semiconductor temperature sensor built in optical sensor chip 7 in the semiconductor optical sensor devices according to the first and second embodiments will be described below with reference to FIG. 7.

In FIG. 7, NPN transistors Q₁ and Q₂ which exhibit the same characteristics, MOSFETs Q₃ through Q₁₁ which exhibit the same characteristics, a current source IS, resistors R, R₁, and R₂, a capacitor C, and an amplifier A are connected in the illustrated manner. That is to say, the gates of MOSFETs Q₈, Q₅, Q₆, and Q₁₀ are connected commonly to current source IS. The gates of MOSFETs Q₃ and Q₄ are connected to the drain of MOSFET Q₄. The gates of MOSFETs Q₉ and Q₁₁ are connected to the drain of MOSFET Q₉.

Although one NPN transistor Q₂ is shown, m-NPN transistors are connected in parallel to each other in practice. In FIG. 7, the reference numeral Q₂ represents the m-NPN transistors collectively. Further, although only one MOSFET Q₁₁ is shown, n-MOSFETs are connected in parallel to each other in practice. In FIG. 7, the reference numeral Q₁₁ represents the n-MOSFETs collectively.

A series circuit of NPN transistor Q₁ and MOSFETs Q₃, Q₅ and a series circuit of NPN transistor Q₂ and MOSFETs Q₄, Q₆ constitute a first current mirror circuit. A current I_{PTAT} determined by MOSFET Q₅ flows through these series circuits. A series circuit of MOSFETs Q₉ and Q₁₀ and a series circuit of MOSFET Q₁₁ and resistor R₂ constitute a second current mirror circuit. A current (n·I_{PTAT}) n times as high as the current I_{PTAT} that flows through series circuit of MOSFETs Q₉ and Q₁₀ flows through resistor R₂.

When the voltage between the base and the emitter of transistor Q₁ and the voltage between the base and the emitter of transistor Q₁ are represented by V_{BE1} and V_{BE2} respectively, the following equation (2) holds, since the source potentials of MOSFET Q₃ and Q₄ are the same with each other.
V_{BE1}=V_{BE2}+I_{PTAT}·R₁ (2)

It is known that the collector current I_{c} of a transistor is given by the following equation (3).
I_{C}=I_{S}·exp (V_{BE}/V_{T}) (3)

Here, I_{S} is a saturation current (constant) and V_{T}=kT/q, in which k is the Boltzmann constant, T the absolute temperature, and q the electron charge quantity (absolute value).

Since the collector current of transistor Q₁ is equal to I_{PTAT}, the following equation (4) holds based on the equation (3).
I_{PTAT}=I_{S}·exp (V_{BE}/Vₜ) (4)

By transforming the equation (4), the following equations (5) and (6) are obtained.
I_{PTAT}/I_{S}=exp (V_{BE}/Vₜ) (5)
ln(I_{PTAT}/I_{S})=V_{BE}/Vₜ (6)

Therefore, the following equation (7) is obtained.
V_{BE}=V_{T}·ln (I_{PTAT}/I_{S}) (7)

Based on the equation (7), equation (2) can be replaced by the following equation (8) and the following equation (9) is obtained from the equation (8).
V_{T}·ln (I_{PTAT}/I_{S})=V·ln (I_{PTAT}/mI_{S})+I_{PTAT}·R₁ (8)
I_{PTAT}=V_{T}·ln (m)/R₁ (9)

Since V_{T} is proportional to the absolute temperature as described earlier, the current I_{PTAT} is also proportional to the absolute temperature. By detecting the voltage expressed by the following equation (10) obtained by converting the current I_{PTAT} with resistor R₂ and amplifier A, the voltage Vout is proportional not only to the temperature of the NPN transistor but also to the temperature of the optical sensor chip incorporating the semiconductor temperature sensor therein is obtained.
Vout=(2nR₂/R₁)·V_{T}·ln (m) (10)

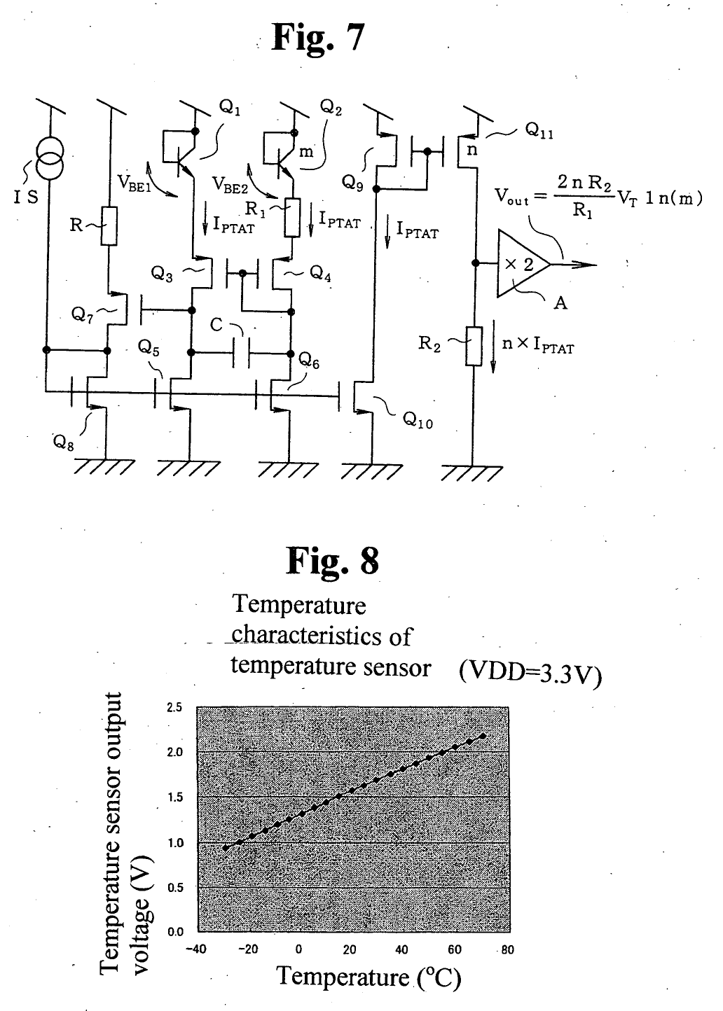

FIG. 8 is a graph describing the typical characteristics of a temperature sensor. By using the semiconductor temperature sensor that works as described above, it is possible to detect the temperature of optical sensor chip 7 according to the first embodiment or the second embodiment. Therefore, it is possible to detect the temperature of lens 3a or lenses 3A and 3B arranged on the other side of optical sensor chip 7 with silicone gel 9 exhibiting a high thermal conductivity interposed therebetween.

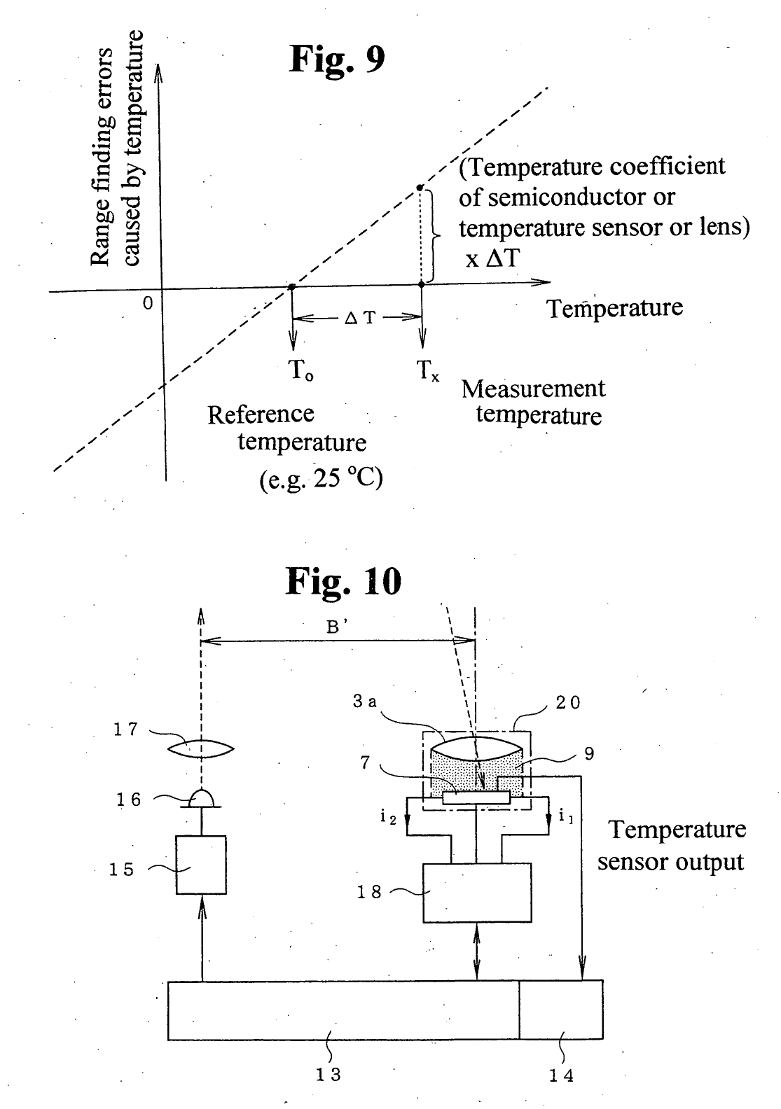

FIG. 9 is a graph describing the errors caused in range finding using the semiconductor optical sensor device according, for example, to the second embodiment.

The optical sensor device according to the second embodiment, is mounted on a camera as a range finder. The initial adjustment is conducted at a reference temperature (e.g. 25° C.) and the initial range finding error is set at 0. The outputs from the semiconductor temperature sensors built in the respective optical sensor chips are different at the same temperature from chip to chip due to the differences among the individual temperature sensors. However, the gradients of the characteristic lines for the respective temperature sensors as described in FIG. 9 are the same, since the temperature coefficients of the respective temperature sensors are the same.

Therefore, the value obtained by multiplying the difference ÄT between the actual measurement temperature Tₓ and the reference temperature Tₒ and the temperature coefficient of the optical sensor (the temperature coefficient of the lenses) is the same for all the optical sensor chips. Therefore, if the initial adjustment is conducted based on the common reference position (the position, at which the range finding error is 0), the same range finding errors will be detected for all the optical sensor chip. Thus, the errors to be corrected are obtained uniquely.

In other words, it is not necessary to initially adjust the output temperature from the temperature sensor to be within a certain range nor to measure the absolute value of the temperature in the actual range finding.

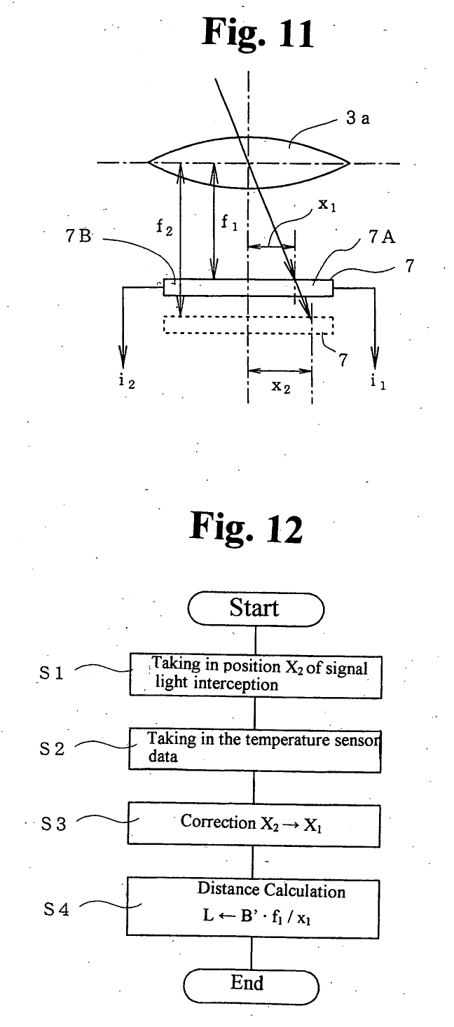

FIG. 10 is a schematic view describing the structure of an active automatic focusing system according to a third embodiment of the invention. FIG. 11 is an enlarged view of the semiconductor optical sensor device 20 shown in FIG. 10.

The active automatic focusing system according to the third embodiment employs the semiconductor optical sensor device according to the first embodiment.

Referring now to FIG. 10, an infrared LED 16 is connected to a CPU 13 via a driver 15. A projector lens 17 irradiates an infrared ray from infrared LED 16 to an object. As described earlier in connection with the first embodiment, semiconductor optical sensor device 20 incorporates therein lens 3a and optical sensor chip 7. The semiconductor temperature sensor described above is formed on optical sensor chip 7 and silicone gel 9 is filled into the space between lens 3a and optical sensor chip 7 for a transparent filler.

The currents i₁ and i₂ outputted from optical sensor chip 7 are inputted to an IC 18 for range finding. The output signal (AF signal) from IC 18 is inputted to CPU 13 described above. The output signal from the semiconductor temperature sensor in optical sensor chip 7 is inputted to an A/D converter 14. A/D converter 14 converts the temperature measured by the temperature sensor to a digital signal employable to distance calculation in CPU 13.

In FIG. 10, the reference symbol B′ represents the distance between the centerline (optical axis) of projector lens 17 and the centerline (optical axis) of lens 3a.

In FIG. 11 which shows the optical sensor device 20 (the silicone gel is not illustrated), optical sensor chip 7 includes optical sensor arrays 7A and 7B on the right and left hand sides of the center thereof, respectively. Optical sensor chip 7 outputs current signals i₁ and i₂ indicating the positions of light interception on the respective optical sensor arrays 7A and 7B. This configuration facilitates calculating the distance x₁ between the position of light interception on optical sensor chip 7 and the centerline thereof (the centerline of lens 3a) based on the magnitudes of current signals i₁ and i₂. Hereinafter, descriptions will be made assuming that the distance x₁ is equivalent to the position of light interception.

Now, it is assumed that the distance f₁ between lens 3a and optical sensor chip 7 changes to f₂ relatively due to the temperature change of lens 3a in optical sensor device 20 from the reference temperature (by the temperature difference ÄT) and that the position of light interception on optical sensor chip 7 also changes from x₁ to x₂.

The distance L from lens 3a to an object (not shown) is obtained from L=(B′·f₁)/x₁ based on the principle of triangulation.

The relation f₁: x₁=f₂: x₂ holds in FIG. 11. The distance f₁ is known as a design parameter. The distance f₂ after the change corresponding to the temperature difference ÄT can be calculated in advance. The position of light interception x₂ after the change is obtained from the current signals i₁ and i₂. Therefore, the position of light interception x₁=(f₁·x₂)/f₂ can be obtained.

Therefore, the distance L from lens 3a to the object can be calculated from the relational expression L=(B′·f₁)/x₁ described above.

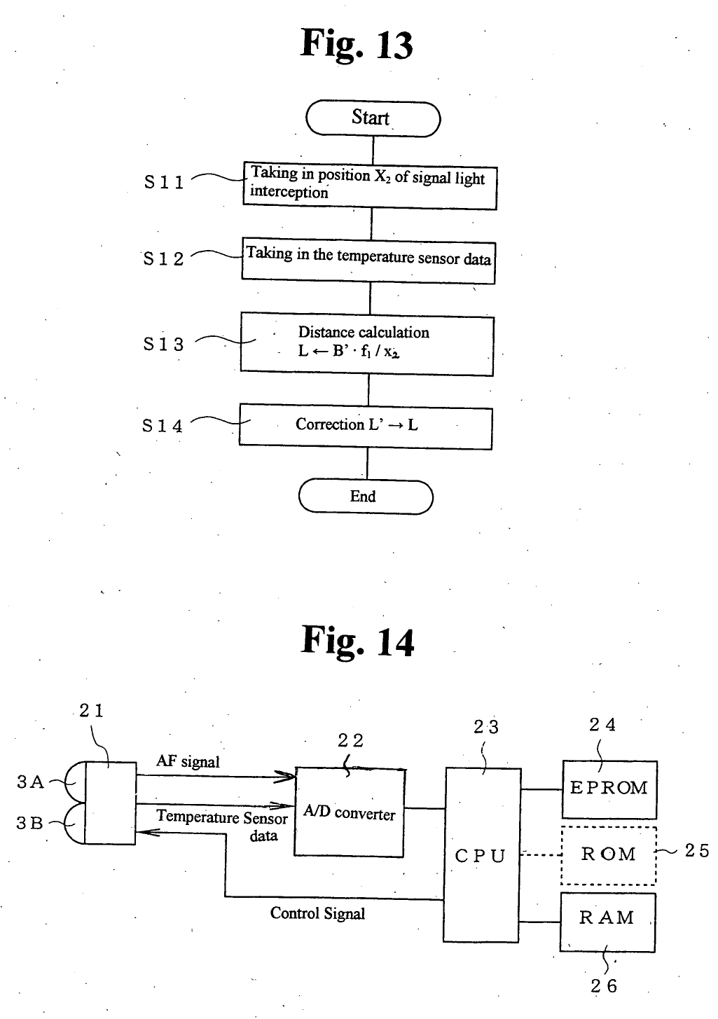

FIGS. 12 and 13 are flow charts describing the temperature corrections described above for calculating the object distance L after correcting the distance from x₂ to x₁. FIG. 13 is a flow chart for obtaining the object distance L first by calculating the object distance L′ based on the distance x₂ and, then, by correcting the distance L′.

In FIG. 12, the distance x₂ and the temperature data from the temperature sensor are taken in (the steps S1 and S2). Then, x₂ is corrected to x₁ (the step S3). Then, the distance L is calculated (the step S4).

In FIG. 13, the distance x₂ and the temperature data from the temperature sensor are taken in (the steps S11 and S12). Then, the distance L′ is calculated (the step S13). Then, the distance L is obtained by correcting the distance L′ (the step S14).

By any of these methods described above, the object distance L is obtained accurately independently of the temperature difference ÄT.

FIG. 14 is a schematic block diagram of a range finder according to the fourth embodiment of the invention and is such as to use the semiconductor optical sensor device according to the second embodiment.

Referring now to FIG. 14, numeral 21 is a semiconductor sensor device explained as the second embodiment of the invention, and an AF signal and a temperature sensor data outputted from the semiconductor sensor device 21 is inputted to an A/D converter 22. The AF signal is a digital signal corresponding to the above described phase difference x=xₐ+x_{b} outputted from optical sensor 7 (optical sensor arrays 7a and 7b) shown in FIG. 5.

The digital signal outputted from A/D converter 22 is inputted to a CPU 23 that conducts range finding calculation. CPU 23 outputs a control signal to optical sensor device 21. An EPROM 24 stores various constants such as the distance f between lenses 3A, 3B and optical sensor chip 7, the AF value, at which the image at the infinity point is picked up, and the output voltage from the temperature sensor at the reference temperature (25° C.). A ROM 25 stores the programs. (Alternatively, the programs may be stored in EPROM 24.) A RAM 26 stores the AF signals and the output voltages from the temperature sensor.

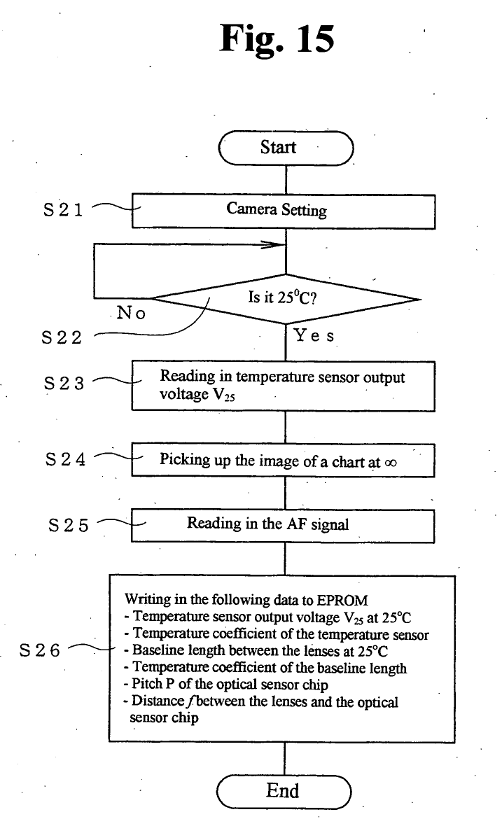

FIG. 15 is a flow chart describing the initial adjustment steps for the range finder shown in FIG. 14. FIG. 15 shows the process of storing the various data necessary for the actual range finding in EPROM 24. The range finder is used in the state of being mounted on a camera.

The range finder is set on a camera (the step S21). Then, judgment is conducted to know whether the present temperature is the reference temperature (25 C.) or not (the step S22). When it is confirmed that the present temperature is the reference temperature, the output voltage V₂₅ from the temperature sensor in optical sensor chip 7 (the voltage corresponding to the temperature of lenses 3A and 3B) is read into CPU 23 via A/D converter 22 (the step S23). Then, the image of a chart at the infinity point is picked up using a collimator and such an optical means (the step S24). The AF signal outputted from optical sensor chip 7 in the step S24 is read in CPU 23 (the step S25).

Next, the temperature sensor output voltage V₂₅ read into in the step S23, the temperature coefficient of the temperature sensor, the baseline length between lenses 3A and 3B, the temperature coefficient of the baseline length, the sensor pitch P of optical sensor chip 7, the distance f between lenses 3A, 3B and optical sensor chip 7 at 25° C., and the AF signal (phase difference) for the infinity point read into in the step S25 are written into EPROM 24 (the step S26). The values other than the temperature sensor output voltage read into in the step S23 and the AF signal (phase difference) about the infinity point read into in the step S25 are known in advance.

Thus, various kinds of data necessary for range finding are stored in EPROM 24.

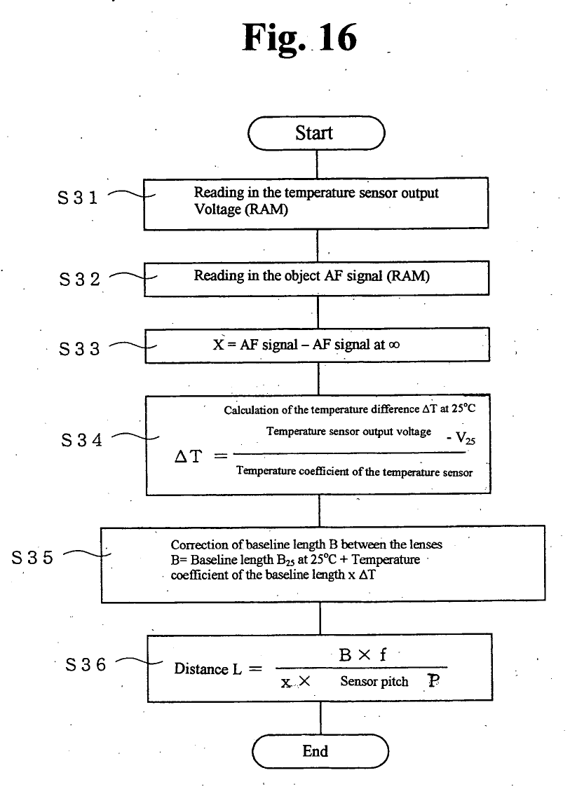

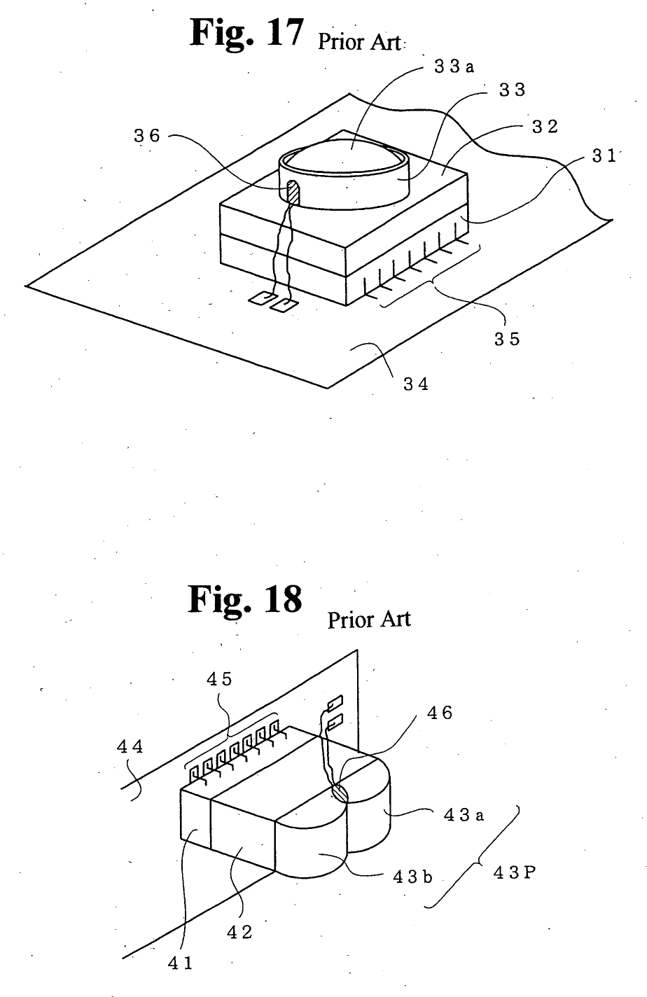

FIG. 16 is a flow chart depicting the steps of range finding conducted using the range finder adjusted initially as described above.

First, the output voltage from the temperature sensor in optical sensor chip 7 is read into CPU 23 via A/D converter 22 and stored in RAM 26 (the step S31). Next, the AF signal (phase difference) outputted from optical sensor chip 7 in response to picking up the object image is read into CPU 23 and stored in RAM 26 (the step S32).

Next, CPU 23 obtains the difference between the AF signal stored in the step S32 and the AF signal, obtained in picking up the image at the infinity point and stored in the initial adjustment, and uses the obtained difference as a distance x (the step S33). The distance x corresponds to xₐ+x_{b} in FIG. 6.

In addition, the difference ÄT between the temperature of lenses 3A, 3B and the reference temperature 25° C. is obtained from the following equation (11) (the step S34).
ÄT=(the temperature sensor output voltage−V₂₅)/(the temperature coefficient of the temperature sensor) (11)

Here, V₂₅ is the output voltage from the temperature sensor at 25° C. as described above and stored in EPROM 24 together with the temperature coefficient of the temperature sensor. In other words, it is not necessary to measure the absolute value of the temperature, at which the actual measurement is conducted. The CPU 23 then corrects the baseline length B between lenses 3A and 3B from the following equation (12) using the above described ÄT (the step S35).
B=(the baseline length B₂₅ at 25° C.)+(the temperature coefficient of the baseline length)×ÄT (12)

The baseline length at 25° C. and the temperature coefficient of the baseline length are stored in EPROM 24. By using the equation (12), the error caused by the temperature difference ÄT in the baseline length B between lenses 3A and 3B is corrected.

CPU 23 calculates the distance L between lenses 3A, 3B and the object from the following equation (13) based on the principle of triangulation (the step S36).
The distance L=(B×f)/(x times sensor pitch P) (13)

Here, f is the distance between lenses 3A, 3B and optical sensor chip 7.

Thus, the object distance L is measured accurately independently of the temperature of lenses 3A and 3B at the time of range finding. Although the distances x and f are affected by the temperature at the time of range finding, it is not necessary to consider the influences of the temperature, since the ratio of the distances x and f does not change.

The range finder according to the fourth embodiment is described in connection with optical sensor device 21 shown in FIG. 14 provided with quantizer circuits 10a and 10b shown in FIG. 6 and such functions assuming the range finding based on the principle (range finder) described in FIG. 6 using the optical sensor device according to the second embodiment (shown in FIGS. 4 and 5). Alternatively, CPU 23 in FIG. 14 may be provide with these functions without any problem.

The disclosure of Japanese patent application No. 2004-293778 filed on Oct. 6, 2004 is incorporated herein.

While the invention has been described with reference to only a limited number of embodiments, the various modifications and changes that can be made without departing from the scope of the invention, which is limited only by the appended claims, will be self-evident to the person skilled in this art or the art most closely related thereto, given the preceding description.

What is claimed is:

1. A semiconductor optical sensor device comprising:
focusing means for focusing light from an object;
a semiconductor optical sensor chip on which an image of the object is formed through the focusing means;
a transparent filler filled between the focusing means and the semiconductor optical sensor chip, the transparent filler exhibiting a high thermal conductivity;
wherein said semiconductor optical sensor chip includes a temperature sensor which measures a temperature of the focusing means via the transparent filler.

2. A semiconductor optical sensor device according to claim 1, wherein the focusing means comprises one lens that forms the image of the object on the semiconductor optical sensor chip to pick up the image of the object.

3. A semiconductor optical sensor device according to claim 1, wherein the focusing means comprises a lens that focuses a reflected light from the object reflecting light irradiated from external light emitting means; and
the semiconductor optical sensor device further comprises calculating means that calculates a distance between the lens and the object based on a principle of triangulation using the temperature measured by the temperature sensor, a distance between the light emitting means and the lens, a position of light interception on the semiconductor optical sensor chip where the reflected light via the lens is intercepted, and a distance between the lens and the semiconductor optical sensor chip.

4. A semiconductor optical sensor device according to claim 1, wherein the focusing means comprises a pair of lenses; and
the semiconductor optical sensor device further comprises calculating means that calculates a distance between the pair of lenses and the object based on a principle of triangulation using the temperature measured by the temperature sensor, a baseline length between the lenses, a position of light interception on the semiconductor optical sensor chip where the light via the lenses is intercepted, and a distance between the lenses and the semiconductor optical sensor chip.

5. A semiconductor optical sensor device according to claim 1, wherein the temperature sensor comprises a semiconductor temperature sensor that obtains an output voltage proportional to a temperature of a PN-junction of a semiconductor device formed in the semiconductor optical sensor chip.

6. A range finding method using the semiconductor optical sensor device described in claim 3, comprising the steps of:
correcting a position of light interception on the semiconductor optical sensor chip using the temperature difference between the temperature measured by the temperature sensor and a reference temperature; and
measuring the distance between the lens and the object based on the principle of triangulation using a corrected position of light interception.

7. A range finding method using the semiconductor optical sensor device described in claim 3, comprising the steps of:
obtaining the distance between the lens and the object based on the principle of triangulation without considering the temperature measured by the temperature sensor; and
correcting the obtained distance using a temperature difference between the temperature measured by the temperature sensor and a reference temperature.

8. A range finding method using the semiconductor optical sensor device described in claim 4, comprising the steps of:
correcting the baseline length between the lenses using a temperature difference between the temperature measured by the temperature sensor and a reference temperature; and
measuring a distance between the lenses and the object based on the principle of triangulation using the corrected baseline length.
